(19) United States
(12) Patent Application Publication
(10) Pub. No.: US 2021/0328159 A1
(43) Pub. Date: Oct. 21, 2021

(54) FLEXIBLE DISPLAY SUBSTRATE AND ORGANIC LIGHT EMITTING DIODE DISPLAY DEVICE

(71) Applicant: Wuhan China Star Optoelectronics Semiconductor Display Technology Co., Ltd., Wuhan, Hubei (CN)

(72) Inventor: Sisi Zhou, Wuhan, Hubei (CN)

(21) Appl. No.: 16/500,697

(22) PCT Filed: Apr. 29, 2019
(86) PCT No.: PCT/CN2019/084886

§ 371 Date: Oct. 3, 2019

(30) Foreign Application Priority Data
Dec. 18, 2018 (CN) 201811550859.4

(51) Int. Cl. H01L 51/00; H01L 27/32; G09F 9/30

(52) U.S. Cl. CPC H01L 51/0097; H01L 2251/5338; G09F 9/301; H01L 27/3276

(57) ABSTRACT

A flexible display substrate includes a flexible substrate and a trace. The flexible substrate includes a bend region, and the trace disposed in the bend region. The bend region includes at least one via hole, and the trace includes a first metal trace and a second metal trace, and the first metal trace and the second metal trace are electrically connected to each other through the at least one via hole at an edge of the bend region. In addition, an organic light emitting diode (OLED) display device including the flexible display substrate is provided.

### BACKGROUND OF INVENTION

### Field of Invention

The present invention relates to a flexible display substrate, and more particularly, to a flexible display substrate used for an organic light emitting diode (OLED) display device.

### Description of Prior Art

Organic light emitting diode (OLED) panels have high contrast, wide color gamut, low power consumption, and foldability. In order to make OLED display devices have narrow frames, it is necessary to bend a lower frame of a flexible substrate to a back side of the flexible display substrate. During bending of the flexible substrate, metal traces are easily to be cracked or even broken, which results in signal lines not being able to transmit signals. It is necessary to improve configuration of the metal traces in the bend region of the flexible substrate, to solve problems in the prior art.

### SUMMARY OF INVENTION

A flexible display substrate includes a flexible substrate and a trace. The flexible substrate includes a bend region, and the trace disposed in the bend region. The bend region includes at least one via hole, and the trace includes a first metal trace and a second metal trace, and the first metal trace and the second metal trace are electrically connected to each other through the at least one via hole at an edge of the bend region.

In one embodiment, the at least one via hole includes a first via hole and a second via hole, and the first metal trace and the second metal trace are electrically connected to each other through the first via hole and the second via hole at the edge of the bend region.

In one embodiment, the at least one via hole has a bore diameter of 2.5 μm to 5 μm.

In one embodiment, the trace further includes a third metal trace or more metal traces.

In one embodiment, material of the trace includes molybdenum, aluminum, titanium, or an alloy thereof.

In one embodiment, the trace includes a scan line, a data signal line, a clock signal line, or a touch signal line.

In one embodiment, the first metal trace and the second metal trace are disposed independently from each other.

In one embodiment, the flexible substrate is a TFT (thin film transistor) array substrate, a substrate on the TFT array substrate or a touch control substrate.

In one embodiment, the flexible display substrate further includes an organic light emitting diode (OLED) component disposed on the flexible substrate. In one embodiment, the first metal trace and the second metal trace are disposed independently from each other and crisscross to each other.

In another embodiment, a flexible display substrate includes a flexible substrate and a trace. The flexible substrate includes a bend region, and the trace disposed in the bend region. The bend region includes at least one via hole, and the at least one via hole has a bore diameter of 2.5 μm to 5 μm, and the trace includes a first metal trace and a second metal trace, and the first metal trace and the second metal trace are electrically connected to each other through the at least one via hole at an edge of the bend region, and the at least one via hole includes a first via hole and a second via hole, and the first metal trace and the second metal trace are electrically connected to each other through the first via hole and the second via hole at the edge of the bend region.

In one embodiment, the trace further includes a third metal trace or more metal traces.

In one embodiment, material of the trace includes molybdenum, aluminum, titanium, or an alloy thereof.

In one embodiment, the trace includes a scan line, a data signal line, a clock signal line, or a touch signal line.

In one embodiment, the first metal trace and the second metal trace are disposed independently from each other and crisscross to each other.

In one embodiment, the flexible substrate is a TFT (thin film transistor) array substrate, a substrate on the TFT array substrate or a touch control substrate.

In one embodiment, the flexible display substrate further includes an organic light emitting diode (OLED) component disposed on the flexible substrate. In one embodiment, the first metal trace and the second metal trace are disposed independently from each other and crisscross to each other.

In a further embodiment, a flexible display substrate includes a flexible substrate and a trace. The flexible substrate includes a bend region, and the trace disposed in the bend region. The bend region includes at least one via hole, and the at least one via hole has a bore diameter of 2.5 μm to 5 μm, and the trace includes a first metal trace and a second metal trace, and the first metal trace and the second metal trace are electrically connected to each other through the at least one via hole at an edge of the bend region, and the first metal trace and the second metal trace are disposed independently from each other.

In one embodiment, the trace further includes a third metal trace or more metal traces.

### BRIEF DESCRIPTION OF DRAWINGS

FIG. 1 is a schematic structural view of a bending flexible display substrate.

FIG. 2 is a partial enlarged schematic view of a bend region of a flexible substrate according to one embodiment of the present invention.

FIG. 3 is a schematic view of a trace and a via hole that are disposed according to one embodiment of the present invention.

FIG. 4 is a cross-sectional view of the bend region (AA′) of a flexible substrate shown in FIG. 3.

FIG. 5 is a schematic view of a trace and a via hole that are disposed according to another embodiment of the present invention.

### DETAILED DESCRIPTION OF PREFERRED EMBODIMENTS

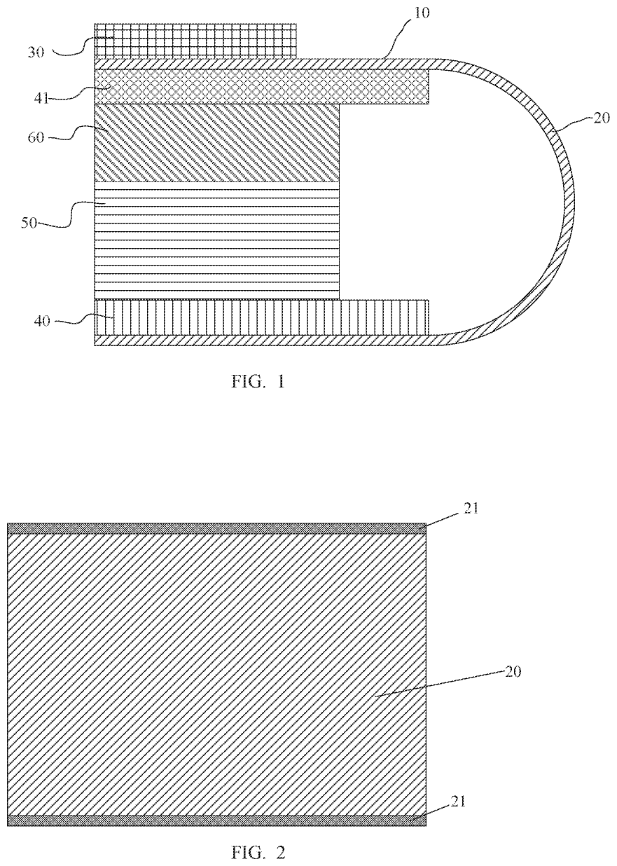

Referring to FIG. 1, it is a schematic structural view of a bending flexible display substrate. The flexible display substrate includes a flexible substrate 10, a bend region 20, a polarizer module 30, a first support layer 40, a second support layer 41, a support component 50, and a foam layer 60. The first support layer 40 and the second support layer 41 are disposed on both inner sides of the flexible substrate 10, and the support component 50 and the foam layer 60 are disposed above an inner side of the first support layer 40. The support component 50 supports the foam layer 60, and the second support layer 41 is disposed above the foam layer 60. The foam layer 60 has a bind function that the second support layer 41 is bound on the foam layer 60. The first support layer 40 and the second support layer 41 can support the flexible substrate 10. The polarizer module 30 is disposed above the second support layer 41 and the flexible substrate 10 which is bent. In detail, a trace is disposed within the bend region 20 of the flexible substrate 10. An organic light emitting diode (OLED) component (not shown) may be disposed on the flexible substrate 10.

Conventionally, traces are easily to be cracked or even broken in the bend region of the flexible substrate due to excessive stretching, which results that signal cannot be transmitted by signal lines. Accordingly, embodiments are provided to solve problems in the prior art. The embodiments are described in detail below with reference to the accompanying drawings.

In one embodiment, a flexible display substrate includes a flexible substrate and a trace. The flexible substrate includes a bend region, and the trace is disposed in the bend region. The trace includes a first metal trace and a second metal trace, and the first metal trace and the second metal trace are electrically connected to each other through the at least one via hole at an edge of the bend region. At least one via hole is disposed at an edge of the flat region near the bend region. When the flexible substrate is not bent, the first metal trace is disposed on a top surface of the flexible display substrate, and the second metal trace is disposed on a bottom surface of the flexible display substrate. When the flexible substrate is bent, the first metal trace is disposed outside the flexible display substrate, and the second metal trace is disposed inside the flexible display substrate. The first metal trace extends in the flat region and the second metal trace extends in the bend region. The organic light emitting diode (OLED) component is disposed in the flat region.

Referring to FIG. 2, it is a partial enlarged schematic view of a bend region 20 of a flexible substrate 10 according to one embodiment of the present invention. In one embodiment, at least one trace 70 is disposed at an edge 21 of the bend region 20, and the at least one trace 70 is electrically connected to each other through the at least one via hole at the edge 21 of the bend region 20.

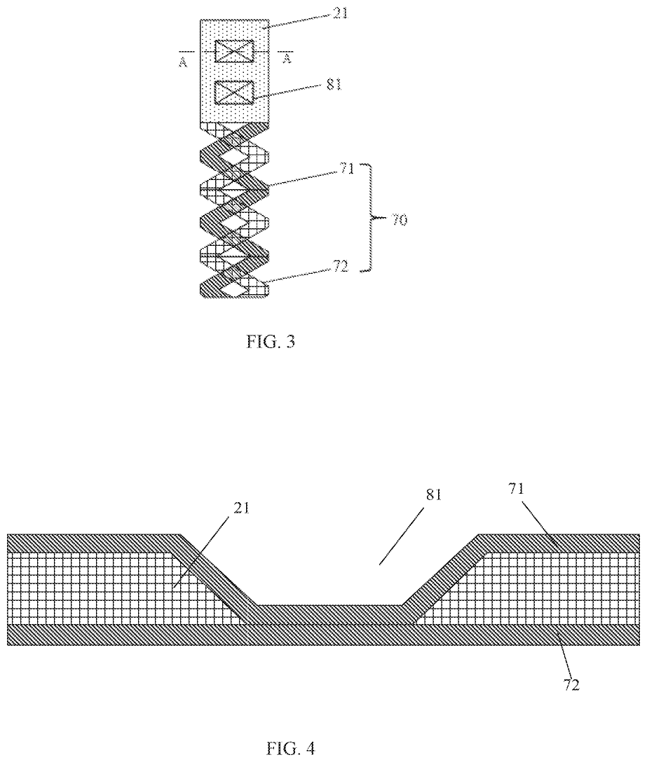

Referring to FIG. 3, it is a schematic view of a trace and a via hole that are disposed according to one embodiment of the present invention. The trace 70 includes a first metal trace 71 and a second metal trace 72. The first metal trace 71 and the second metal trace 72 are disposed independently from each other and crisscross to each other. The first metal trace 71 and the second metal trace 72 are electrically connected to each other through the at least one via hole 80 at an edge 21 of the bend region 20, and the at least one via hole 80 includes a first via hole 81. Specifically, the first via hole has a bore diameter of 2.5 μm to 5 μm, and material of the trace includes, but is not limited, molybdenum, aluminum, titanium, or an alloy thereof. Moreover, the trace includes a scan line, a data signal line, a clock signal line, or a touch signal line, and the flexible substrate is a TFT (thin film transistor) array substrate, a substrate on the TFT array substrate or a touch control substrate. In addition, the trace 70 further includes a third metal trace or more metal traces, which can be adjusted by a skilled person in the art according to actual needs.

Referring FIG. 4, it is a cross-sectional view of the bend region (AA′) of a flexible substrate shown in FIG. 3. In one embodiment, it can be clearly understood that the first metal trace 71 and the second metal trace 72 are electrically connected to each other through the first via hole 81 at the edge 21 of the bend region 20, and the first metal trace 71 and the second metal trace 72 are disposed independently from each other and crisscross to each other.

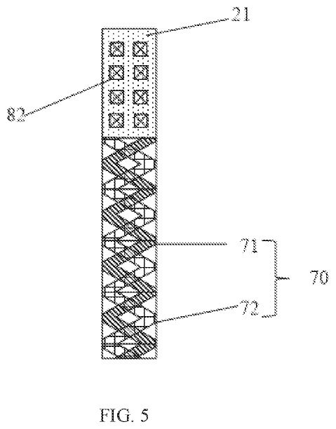

Referring to FIG. 5, it is a schematic view of a trace and a via hole that are disposed according to another embodiment of the present invention. This embodiment shown is similar to the embodiment shown in FIG. 3, except that the at least one via hole 80 includes a second via hole 82. A number of the second via holes 82 are larger than a number of the first via holes 81. However, a size the second via hole 82 size is smaller than a size of the first via hole 81.

In another embodiment, an organic light emitting diode (OLED) display device having the above-mentioned flexible display substrate is provided. It can be known that the flexible display substrate of the embodiment can be applied to various display devices by a skilled person in the art according to actual needs.

In the above, the present invention has been described in the above preferred embodiments, but the preferred embodiments are not intended to limit the scope of the present invention, and a person skilled in the art may make various modifications without departing from the spirit and scope of the present invention. The scope of the present invention is determined by claims.

What is claimed is:

1. A flexible display substrate, comprising:
a flexible substrate, wherein the flexible substrate comprises a bend region; and
a trace disposed in the bend region;
wherein the bend region comprises at least one via hole, the trace comprises a first metal trace and a second metal trace, and the first metal trace and the second metal trace are electrically connected to each other through the at least one via hole at an edge of the bend region.

2. The flexible display substrate according to claim 1, wherein the at least one via hole comprises a first via hole and a second via hole, and the first metal trace and the second metal trace are electrically connected to each other through the first via hole and the second via hole at the edge of the bend region.

3. The flexible display substrate according to claim 1, wherein the at least one via hole has a bore diameter of 2.5 μm to 5 μm.

4. The flexible display substrate according to claim 1, wherein the trace further comprises a third metal trace or more metal traces.

5. The flexible display substrate according to claim 1, wherein material of the trace comprises molybdenum, aluminum, titanium, or an alloy thereof.

6. The flexible display substrate according to claim 1, wherein the trace comprises a scan line, a data signal line, a clock signal line, or a touch signal line.

7. The flexible display substrate according to claim 1, wherein the first metal trace and the second metal trace are disposed independently from each other.

8. The flexible display substrate according to claim 1, wherein the flexible substrate is a TFT (thin film transistor) array substrate, a substrate on the TFT array substrate or a touch control substrate.

9. The flexible display substrate according to claim 1, further comprising an organic light emitting diode (OLED) component disposed on the flexible substrate.

10. The flexible display substrate according to claim 1, wherein the first metal trace and the second metal trace are disposed independently from each other and crisscross to each other.

11. A flexible display substrate, comprising:
a flexible substrate, wherein the flexible substrate comprises a bend region; and
a trace disposed in the bend region;
wherein the bend region comprises at least one via hole, and the at least one via hole has a bore diameter of 2.5 μm to 5 μm, and the trace comprises a first metal trace and a second metal trace, and the first metal trace and the second metal trace are electrically connected to each other through the at least one via hole at an edge of the bend region, and the at least one via hole comprises a first via hole and a second via hole, and the first metal trace and the second metal trace are electrically connected to each other through the first via hole and the second via hole at the edge of the bend region.

12. The flexible display substrate according to claim 11, wherein the trace further comprises a third metal trace or more metal traces.

13. The flexible display substrate according to claim 11, wherein material of the trace comprises molybdenum, aluminum, titanium, or an alloy thereof.

14. The flexible display substrate according to claim 11, wherein the trace comprises a scan line, a data signal line, a clock signal line, or a touch signal line.

15. The flexible display substrate according to claim 11, wherein the first metal trace and the second metal trace are disposed independently from each other and crisscross to each other.

16. The flexible display substrate according to claim 11, wherein the flexible substrate is a TFT (thin film transistor) array substrate, a substrate on the TFT array substrate or a touch control substrate.

17. The flexible display substrate according to claim 11, further comprising an organic light emitting diode (OLED) component disposed on the flexible substrate.

18. The flexible display substrate according to claim 11, wherein the first metal trace and the second metal trace are disposed independently from each other and crisscross to each other.

19. A flexible display substrate comprising:
a flexible substrate, wherein the flexible substrate comprises a bend region; and
a trace disposed in the bend region;
wherein the bend region comprises at least one via hole, and the at least one via hole has a bore diameter of 2.5 μm to 5 μm, and the trace comprises a first metal trace and a second metal trace, and the first metal trace and the second metal trace are electrically connected to each other through the at least one via hole at an edge of the bend region, and the first metal trace and the second metal trace are disposed independently from each other.

20. The flexible display substrate according to claim 19, wherein the trace further comprises a third metal trace or more metal traces.
